(19) United States
(12) Patent Application Publication
(10) Pub. No.: US 2014/0339402 A1
(43) Pub. Date: Nov. 20, 2014

(54) MULTI-OUTPUT TERMINAL CONNECTOR

(71) Applicant: HON HAI PRECISION INDUSTRY CO., LTD., New Taipei (TW)

(72) Inventor: YI-ZHONG SHEU, New Taipei (TW)

(73) Assignee: HON HAI PRECISION INDUSTRY CO., LTD., New Taipei (TW)

(21) Appl. No.: 13/971,924

(22) Filed: Aug. 21, 2013

(30) Foreign Application Priority Data
May 17, 2013 (TW) 102117658

(51) Int. Cl. H01L 31/16; H01L 31/0232

(52) U.S. Cl. CPC H01L 31/16; H01L 31/0232
USPC 250/227.11; 250/578.1

(57) ABSTRACT

A connector includes an input terminal, a light splitting module, and a number of output terminals. The input terminal is electrically connected to a first electrical device, and receives a first electrical signal from a first electrical device, and converts the first electrical signal to a first optical signal. The light splitting module converts the first optical signal to a number of second optical signals. The output terminals correspond to the first light emitters. Each of the output terminals converts a corresponding second optical signal to a second electrical signal, and transmits the second electrical signal to a second electrical device.

### BACKGROUND

1. Technical Field

The present disclosure relates to connectors, in particular, to a multi-output terminal connector.

2. Description of Related Art

Currently, some connectors (such as High-Definition Multimedia Interface, HDMI) includes one input terminal and a number of output terminals. However, the connector uses copper to transmit electrical signals. Because a distance between two adjacent output terminals is very small, electrical signals transmitted through the output terminals can interfere with each other by generating signal crosstalk, and thus the transmission quality of the electrical signals is reduced.

Therefore, it is desirable to provide a connector that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a connector, according to an exemplary embodiment, and the connector having a first light transmission module and a number of second light transmission modules.

FIG. 2 is a schematic view of the first light transmission module of the connector of FIG. 1.

FIG. 3 is a schematic view of each of the second light transmission modules of the connector of FIG. 1.

### DETAILED DESCRIPTION

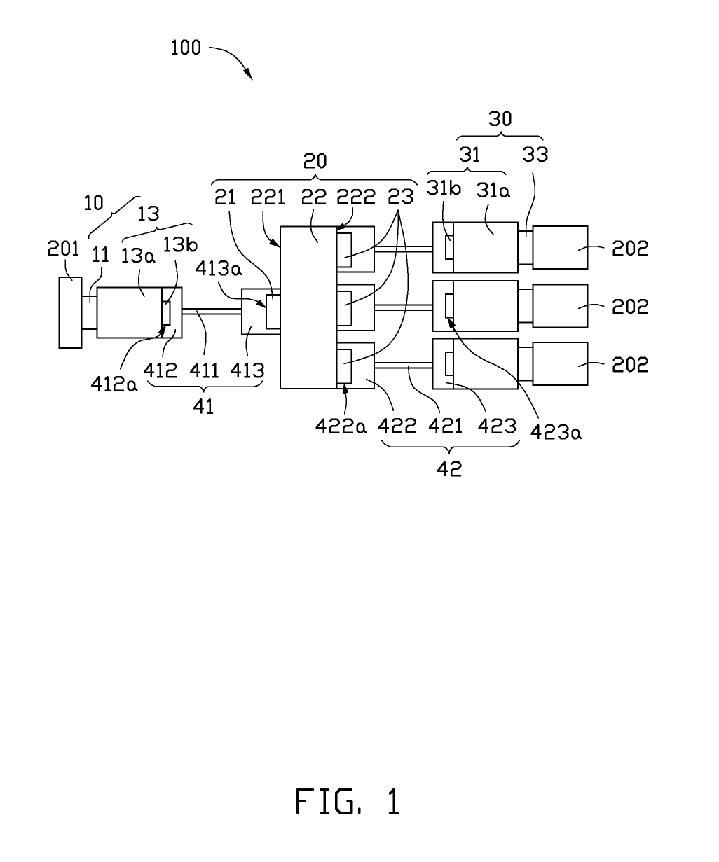

FIG. 1 illustrates a connector 100 in accordance with an embodiment. The connector 100 is used for electrically connecting a first electrical device 201 to a number of second electrical devices 202. The connector 100 includes an input terminal 10, a light splitting module 20, a number of output terminals 30, a first light transmission module 41, and a number of second light transmission modules 42.

The input terminal 10 converts a first electrical signal from the first electrical device 201 (i.e. signal source) to a first optical signal, and transmits the first optical signal to the light splitting module 20.

The light splitting module 20 receives the first optical signal, and converts the first optical signal into a number of same second optical signals. The light splitting module 20 includes a first light receiver 21, a light splitter 22, and a number of first light emitters 23. The first light receiver 21 is used for receiving the first optical signal. The light splitter 22 is used for converting the first optical signal into the second optical signals. The first light emitters 23 respectively correspond to the second optical signals, and are used for emitting the corresponding second optical signals. In this embodiment, the light splitter 22 has a first fixing surface 221 and a second fixing surface 222 opposite to the first fixing surface 221. The first light receiver 21 is positioned on the first fixing surface 221, and the first light emitters 23 are positioned on the second fixing surface 222.

The output terminals 30 respectively correspond to the first light emitters 23, and thus each of the output terminals 30 receives the corresponding second optical signal, and converts the corresponding second optical signal into a second electrical signal. The output terminals 30 also respectively correspond to the second electrical devices 202, and are further used for transmitting the second electrical signals to the corresponding second electrical devices 202.

In particular, the input terminal 10 includes a first electrical connector 11 and a second light emitter 13. The first electrical connector 11 is electrically connected to the first electrical device 201, and is used for receiving the first electrical signal from the first electrical device 201. The second light emitter 13 includes a first main body 13a and a light emitting portion 13b. The first main body 13a is electrically connected to the first electrical connector 11, and is used for converting the first electrical signal to the first optical signal. The light emitting portion 13b is used for emitting the first optical signal.

Each of the output terminals 30 is electrically connected to one of the second electrical devices 202. Each of the output terminals 30 includes a second light receiver 31 and a second electrical connector 33. The second light receiver 31 includes a second main body 31a and a light receiving portion 31b. The light receiving portion 31b is used for receiving the corresponding second optical signal. The second main body 31a is used for converting the corresponding second optical signal to the second electrical signal. The second electrical connector 33 is electrically connected to the second main body 31a, and is used for transmitting the corresponding second electrical signal to the corresponding second electrical device 202.

In this embodiment, the first light receiver 21 includes a photo diode, the second light receiver 31 includes a photo diode, the first light emitter 23 includes a laser diode or a light emitting diode, and the second light emitter 13 includes a laser diode or a light emitting diode.

The first light transmission module 41 is used for transmitting the first optical signal from the input terminal 13 to the light splitting module 20 with minimal signal loss, and includes a first optical fiber 411, a first optical coupling portion 412, and a second optical coupling portion 413. One end of the first optical fiber 411 is optically connected to the first optical coupling portion 412, the other end of the first optical fiber 411 is optically connected to the second optical coupling portion 413. The first optical coupling portion 412 is detachably positioned on the input terminal 10, and is used for aligning the first optical fiber 411 with the second light emitter 13 to make sure the first optical signal from the second light emitter 13 enters the first optical fiber 411 with minimal signal loss. The second optical coupling portion 413 is detachably positioned on the light splitter 20, and is used for aligning the first optical fiber 411 with the first light receiver 21 to make sure the first optical signal from the first optical fiber 411 enters the first light receiver 21 with minimal signal loss.

The second light transmission modules 42 correspond to the first light emitters 23, and are used for transmitting the second optical signals to the corresponding output terminals 30 with minimal signal loss. Each of the second light transmission modules 42 includes a second optical fiber 421, a third optical coupling portion 422, and a fourth optical coupling portion 423. One end of the second optical fiber 421 is optically connected to the third coupling portion 422, and the other end of the second optical fiber 421 is optically connected to the fourth coupling portion 423. The third optical coupling portion 422 is detachably positioned on the light splitting module 20, and is used for aligning the second optical fiber 421 with the first light emitter 23 to make sure the second optical signal from the first light emitter 23 enters the second optical fiber 421 with minimal signal loss. The fourth coupling portion 423 is detachably positioned on the output terminal 30, and is used for aligning the second optical fiber 421 with the second light receiver 31 to make sure the second optical signal from the second optical fiber 421 enters the corresponding second light receiver 31 with minimal signal loss.

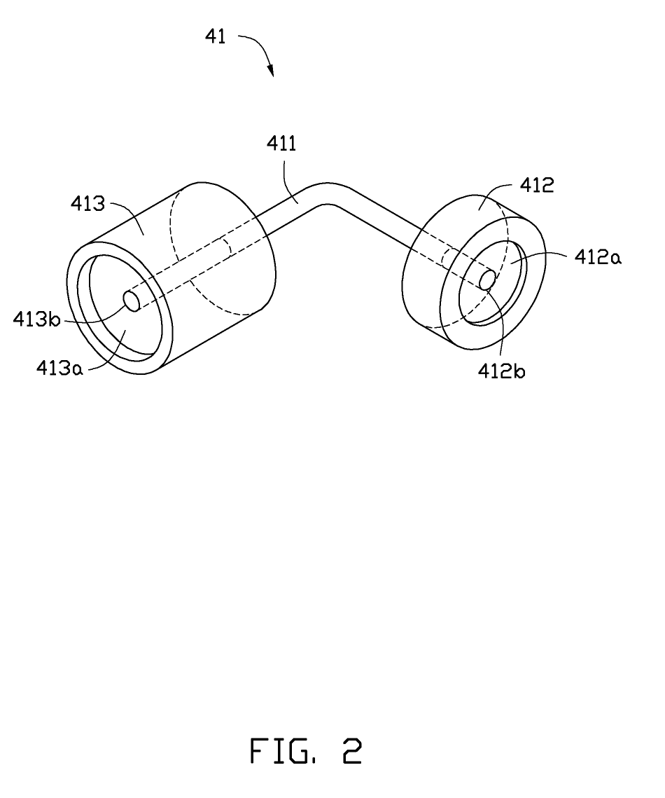

Referring to FIG. 2, the first optical coupling portion 412 defines a first blind hole 412a and a first through hole 412b communicating with the first blind hole 412a. The first blind hole 412a faces the light emitting portion 13b, and is used for receiving the light emitting portion 13b. The one end of the first optical fiber 411 is inserted into the first through hole 412b. The second optical coupling portion 413 defines a second blind hole 413a and a second through hole 413b communicating with the second blind hole 413a. The second blind hole 413a faces the first light receiver 21, and is used for receiving the first light receiver 21. The other end of the first optical fiber 411 is inserted into the second through hole 413b.

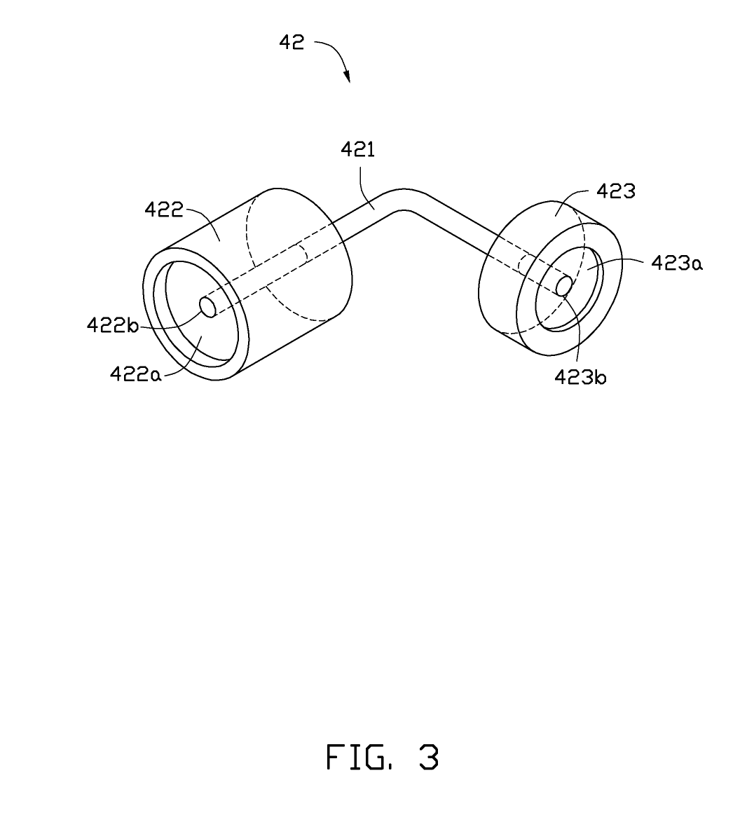

Referring to FIG. 3, the third coupling portion 422 defines a third blind hole 422a and a third through hole 422b communicating with the third blind hole 422a. The third blind hole 422a faces the first light emitters 23, and is used for receiving the first light emitters 23. The one end of the second optical fiber 421 is inserted into the third through hole 422b. The fourth coupling portion 423 defines a fourth blind hole 423a and a fourth through hole 423b communicating with the fourth blind hole 423a. The fourth blind hole 423a faces the light receiving portion 31b, and is used for receiving the light receiving portion 31b. The other end of the second optical fiber 421 is inserted into the fourth through hole 423b.

By employing the connector 100, the electrical signal is converted to the optical signal to be transmitted. During the transmission process of the optical signal, there are no electromagnetic waves, therefore, signal crosstalk is reduced if not eliminated, and the signal quality is effectively improved.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A connector comprising:
an input terminal electrically connected to a first electrical device, and configured for receiving a first electrical signal from the first electrical device, and converting the first electrical signal to a first optical signal; and
a light splitting module comprising:
a first light receiver configured for receiving the first optical signal;
a light splitter configured for converting the first optical signal to a plurality of second optical signals; and
a plurality of first light emitters corresponding the second optical signals, and configured for emitting the corresponding second optical signals; and
a plurality of output terminals corresponding to the first light emitters, each of the output terminal configured for receiving the corresponding second optical signal, and converting the corresponding second optical signal to a second electrical signal, and then transmitting the second electrical signal to a corresponding second electrical device.

2. The connector of claim 1, wherein the input terminal comprises a first electrical connector and a second light emitter, the first electrical connector is electrically connected to the first electrical device, and is configured for receiving the first electrical signal; the second light emitter is configured for converting the first electrical signal to the first optical signal, and is further configured for emitting the first optical signal.

3. The connector of claim 2, wherein the output terminals are corresponding to the first light emitters, each output terminal comprises a second light receiver and a second electrical connector, the second light receiver is configured for receiving the corresponding second light signal from the first light emitter, and is further configured for converting the second optical signal to the corresponding second electrical signal; the second electrical connector is electrically connected to the second electrical device, and is configured for transmitting the corresponding second electrical signal to the corresponding second electrical device.

4. The connector of claim 3, wherein the first light receiver comprises a photo diode, the second light receiver comprises a photo diode, the first light emitter comprises a laser diode or a light emitting diode, and the second light emitter comprises a laser diode or a light emitting diode.

5. The connector of claim 3, further comprising a first light transmission module configured for transmitting the first optical signal from the input terminal to the first light receiver, wherein the first light transmission module comprises a first optical fiber, a first optical coupling portion, and a second optical coupling portion; one end of the first optical fiber is optically connected to the first optical coupling portion, the other end of the first optical fiber is optically connected to the second optical coupling portion; the first optical coupling portion is detachably positioned on the input terminal, and is configured for aligning the first optical fiber with the second light emitter; the second optical coupling portion is detachably positioned on the splitting module, and is configured for aligning the first optical fiber with the first light receiver.

6. The connector of claim 5, wherein the second light emitter comprises a first main body and a light emitting portion; the first optical coupling portion defines a first blind hole and a first through hole communicating with the first blind hole; the first blind hole faces the input terminal, and is configured for receiving the light emitting portion; the one end of the first optical fiber is inserted into the first through hole.

7. The connector of claim 6, wherein the second optical coupling portion defines a second blind hole and a second through hole communicating with the second blind hole;
the second blind hole faces the first light receiver, and is configured for receiving the first light receiver; the other end of the first optical fiber is inserted into the second through hole.

8. The connector of claim 7, further comprises a plurality of second light transmission modules configured for transmitting the second optical signals from the light splitting module to the output terminals, wherein the second light transmission modules correspond to the first light emitters, each of the second light transmission modules comprises a second optical fiber, a third optical coupling portion, and a fourth optical coupling portion; one end of the second optical fiber is optically connected to the third optical coupling portion, and the other end of the second optical fiber is optically connected to the fourth optical coupling portion; the third optical coupling portion is detachably positioned on the light splitting module, and is configured for aligning the second optical fiber with the first light receiver; the fourth optical coupling portion is detachably positioned on the output terminal, and is configured for aligning the second optical fiber with the second light receiver.

9. The connector of claim 8, wherein the third optical coupling portion defines a third blind hole and a third through hole communicating with the third blind hole; the third blind hole faces the first light emitter, and is configured for receiving the first light emitter; the one end of the second optical fiber is inserted into the third through hole.

10. The connector of claim 9, wherein each of the second light receivers comprises a second main body and a light receiving portion; the fourth optical coupling portion defines a fourth blind hole and a fourth through hole communicating with the fourth blind hole; the fourth blind hole faces the light receiving portion, and is configured for receiving the light receiving portion; and the other end of the optical fiber is inserted into the fourth through hole.

11. The connector of claim 1, wherein the light splitter has a first fixing surface and a second fixing surface opposite to the first fixing surface, the first light receiver is positioned on the first fixing surface, and the first light emitters are positioned on the second fixing surface.
